(19) United States
(12) Patent Application Publication
(10) Pub. No.: US 2023/0055891 A1
(43) Pub. Date: Feb. 23, 2023

(54) Transistor Device and Method of Fabricating a Transistor Device

(71) Applicant: Infineon Technologies Austria AG, Villach (AT)

(72) Inventors: Oliver Blank, Villach (AT); Cesar Augusto Braz, Villach (AT); Yan Gao, San Diego, CA (US); Olivier Guillemant, Villach (AT); Franz Hirler, Isen (DE); David Laforet, Villach (AT); Peter Lagger, Villach (AT); Cédric Ouvrard, München (DE); Elias Pree, Villach (AT); Li Juin Yip, Villach (AT)

(21) Appl. No.: 17/796,133

(22) PCT Filed: Feb. 7, 2020
(86) PCT No.: PCT/EP2020/053062

§ 371 Date: Jul. 28, 2022

(51) Int. Cl. H01L 29/78; H01L 29/06; H01L 29/66; H01L 29/10; H01L 29/40; H01L 27/088; H01L 21/8234

(52) U.S. Cl. CPC H01L 29/7813; H01L 29/0696; H01L 29/66734; H01L 29/1095; H01L 29/407; H01L 29/401; H01L 27/088; H01L 29/0607; H01L 21/823475; H01L 21/823487

(57) ABSTRACT

In an embodiment, a transistor device comprises a semiconductor body comprising a plurality of transistor cells comprising a drift region of a first conductivity type, a body region of a second conductivity type forming a first pn junction with the drift region, the second conductivity type opposing the first conductivity type, a source region of the first conductivity type forming a second pn junction with the body region, a columnar field plate trench extending into a major surface of a semiconductor body and comprising a columnar field plate and a gate trench structure extending into the major surface of the semiconductor body and comprising a gate electrode. At least one of the depth and doping level of the body region locally varies within the transistor cell to improve VGSTH homogeneity within the transistor cell.

### BACKGROUND

Common transistor devices for power applications include Si CoolMOS®, Si Power MOSFETs, and Si Insulated Gate Bipolar Transistors (IGBTs). U.S. Pat. No. 9,680,004 B2 discloses a power MOSFET including a metal gate electrode in a gate trench having a stripe shape. The power MOSFET also includes a field plate in a field plate trench which has a columnar or needle shape. The field plate provides charge compensation and offers an opportunity to reduce the area specific on resistance of the MOSFET device.

Transistor devices having even better performance would be desirable.

### SUMMARY

According to the invention, a transistor device comprises a semiconductor body comprising a plurality of transistor cells comprising a drift region of a first conductivity type, a body region of a second conductivity type forming a first pn junction with the drift region, the second conductivity type opposing the first conductivity type, a source region of the first conductivity type forming a second pn junction with the body region, a columnar field plate trench extending into a major surface of a semiconductor body and comprising a columnar field plate and a gate trench structure extending into the major surface of the semiconductor body and comprising a gate electrode. At least one of the depth and doping level of the body region locally varies within the transistor cell to improve VGSTH homogeneity within the transistor cell.

In some embodiments, the gate trench structure comprises a first section extending in a first lateral direction and a second section extending in a second lateral direction that is different from the first lateral direction, wherein the second section intersects with the first section at an intersection.

The angle α formed between the first and second lateral sections may be 0°<α<180°.

In some embodiments, the depth of the body region is greater at the intersection of the gate trench structure than in a region bounding the columnar field plate trench and/or the doping level of the body region is higher at the intersection of the gate trench structure than in a region bounding the columnar field plate trench.

In some embodiments, a maximum dopant concentration at the intersection of the gate trench is at least 1.1 times and at most ten times a maximum dopant concentration of a region bounding the columnar field plate trench.

In some embodiments, a maximum net dopant concentration of the semiconductor body at a position adjacent a side wall of the intersection of the gate trench is at least 1.1 times or at least 1.2 times and at most ten times a maximum net dopant concentration of the semiconductor body at a position adjacent a side wall of the columnar field plate trench.

In some embodiments, in a plane of the semiconductor body, a maximum net dopant concentration of the semiconductor body at a position adjacent a side wall of the intersection of the gate trench is at least 1.1 times or at least 1.2 times and at most ten times a maximum net dopant concentration of the semiconductor body at a position adjacent a side wall of the columnar field plate trench.

In some embodiments, the depth of the body region in the region of the intersection is tᵢₙₜ and the depth of the body region adjacent the columnar field plate trench is t_{body}, and the doping level of the body region at the intersection is Dᵢₙₜ and the doping level of the body region adjacent the columnar field plate trench is D_{body}, wherein tᵢₙₜ>1.05t_{body} or tᵢₙₜ>1.01t_{body} and/or Dᵢₙₜ22 1.1D_{body} or Dᵢₙₜ>1.2D_{body}

In some embodiments, in a plane of the semiconductor body that is positioned between the main surface of the semiconductor body and the depth t_{body}, the maximum net dopant concentration of the semiconductor body at a lateral position adjacent the side wall of the intersection of the gate trench is at least 1.1 times or at least 1.2 times and at most ten times the maximum net dopant concentration of the semiconductor body at the lateral position adjacent the side wall of the columnar field plate trench.

In some embodiments, the transistor device further comprises a plurality of columnar field plate trenches arranged in a regular array. The regular array may be an array of rows and columns, such as a square grid array, or may be a hexagonal array.

In some embodiments, the first section of the gate trench structure is arranged between adjacent ones of the columnar field plate trenches and the second section of the gate trench structure is arranged between adjacent ones of the columnar plate trenches.

In some embodiments, the gate trench structure comprises a grid structure formed by a plurality of first sections intersecting a plurality of second sections and forming a plurality of intersections, and the gate electrode has a grid structure, wherein a pair of first sections and a pair of second sections bound one of the plurality of columnar field plate trenches.

In some embodiments, the first sections extend substantially parallel to one another, the sections extend substantially parallel to cone another and the first and second sections extend substantially perpendicular to one another and form a square grid or a rectangular grid.

In some embodiments, the gate trench structure comprises a grid structure formed by a plurality of first sections intersecting a plurality of second sections and forming a plurality of intersections, and the gate electrode has a grid structure, wherein the grid structure has a hexagonal form.

In embodiments in which the grid structure is hexagonal, the columnar field plate trenches may be arranged in a regular hexagonal array.

In some embodiments, at least one of the depth and the doping level of the body region varies laterally between adjacent ones of the plurality of intersections and/or between the intersection and the columnar field plate trench.

In some embodiments, the body region comprises a higher doping level in a region adjacent the intersection than in a region positioned between neighbouring two intersections, and/or the body region comprises a higher doping level in a region adjacent the intersection than in a region adjacent the columnar field plate trench, and/or the body region extends deeper into the semiconductor body at the intersection than in a region positioned between two neighbouring intersections, and/or the body region extends deeper into the semiconductor body adjacent the intersection than in a region positioned adjacent the columnar field plate trench.

In some embodiments, the depth of the gate trench at the intersection is greater than the depth of the gate trench adjacent the intersection.

A method of fabricating a transistor device is provided, the transistor device comprising a columnar field plate trench extending into a major surface of a semiconductor body comprising a first conductivity type, the columnar field trench comprising a columnar field plate, and a gate trench structure comprising an elongate gate trench having a length, the elongate gate trench extending into the major surface of the semiconductor body and comprising a gate electrode, a lateral spacing between the columnar field plate trench and the elongate gate trench varying along the length of the elongate gate trench. The method comprises implanting dopants of a second conductivity type into the major surface of the semiconductor body to form a body region in the semiconductor body, wherein the second conductivity type opposes the first conductivity type and implanting dopants of the second conductivity type into predetermined regions of the main surface of the semiconductor body so that at least one of the depth and doping level of the body region varies laterally.

In some embodiments, the dopants of the second conductivity type are implanted into predetermined regions of the main surface of the semiconductor body so that at least one of the depth and doping level of the body region varies laterally and varies locally within each transistor cell of the transistor device to improve VGSTH homogeneity within the transistor cell.

In some embodiments, the dopants of the second conductivity type are implanted into predetermined regions of the main surface of the semiconductor body so that at least one of the depth and doping level of the body region varies laterally with a predetermined pattern, for example has a laterally regular variation in value, across the cell field of the transistor device.

In some embodiments, the method further comprises, after implanting the dopants of the second conductivity type into the regions of the body region, annealing the semiconductor body.

In some embodiments, the method further comprises forming a source region of the first conductivity type in the major surface of the semiconductor body.

In some embodiments, the gate trench structure comprises a first section extending in a first lateral direction and a second section extending in a second lateral direction that is different from the first lateral direction. The second section intersects with the first section at an intersection and the discrete region is arranged at the intersection. The discrete region may extend laterally outwardly from the side wall of the gate trench structure into the semiconductor body by a predetermined distance.

In some embodiments, the transistor device comprises a plurality of columnar field plate trenches in the major surface of the semiconductor body, the plurality of columnar field plate trenches being arranged in a regular array.

In some embodiments, the gate trench structure comprises a grid structure formed by a plurality of first sections intersecting a plurality of second sections to form a plurality of intersections and the gate electrode has a grid structure. A pair of first sections and a pair of second sections laterally surround of the plurality of columnar field plate trenches. The regions are arranged at the intersections so that at least one of the depth and doping level of the body region varies laterally between the columnar field plate trench and the intersection.

The discrete region may extend laterally from the side wall of the gate trench structure towards the side wall of the field plate trench.

In some embodiments, the gate trench structure comprises a grid structure formed by a plurality of first sections intersecting a plurality of second sections to form a plurality of intersections and the gate electrode has a grid structure having a hexagonal form in plan view. The regions are arranged at the intersections so that at least one of the depth and doping level of the body region varies laterally between the columnar field plate trench and the intersection.

The discrete region may extend laterally from the side wall of the gate trench structure towards the side wall of the field plate trench.

In some embodiments, the intersections of the gate trench structure are formed in the regions.

Those skilled in the art will recognize additional features and advantages upon reading the following detailed description, and upon viewing the accompanying drawings.

### BRIEF DESCRIPTION

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

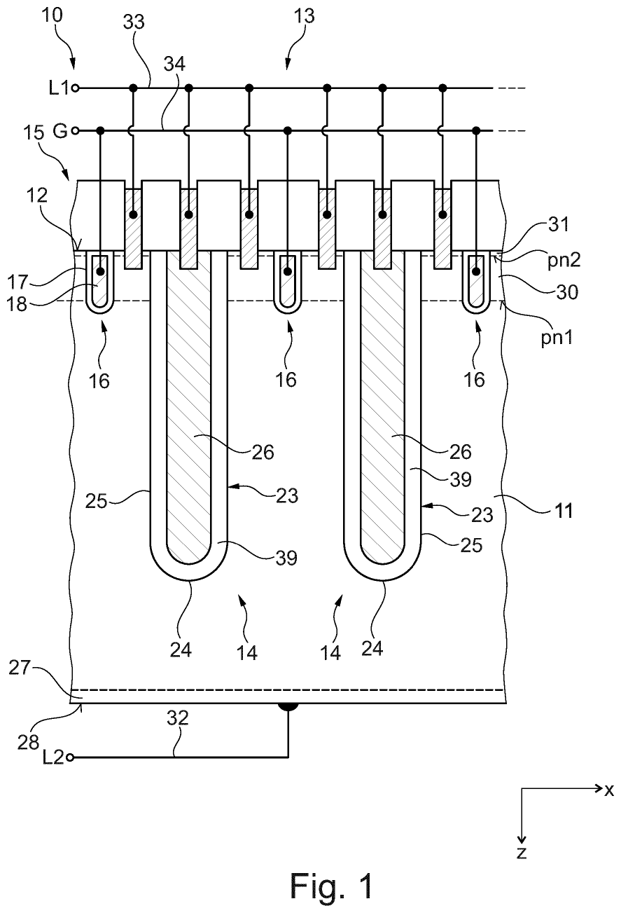

FIG. 1 illustrates a cross-sectional view of a transistor device according to an embodiment.

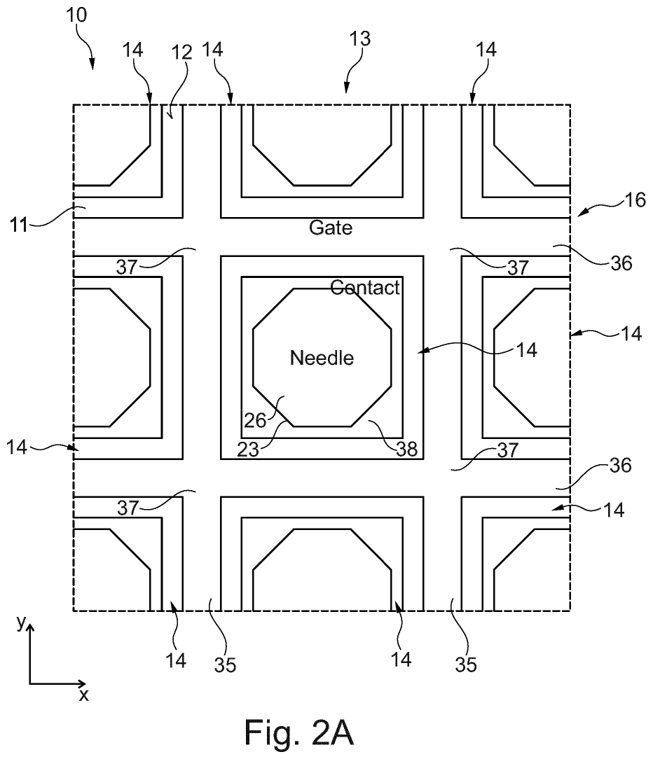

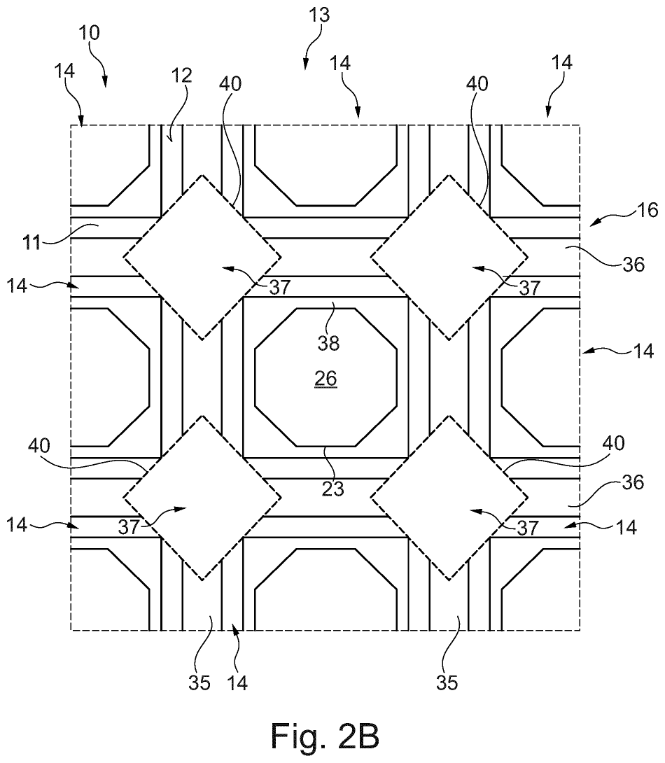

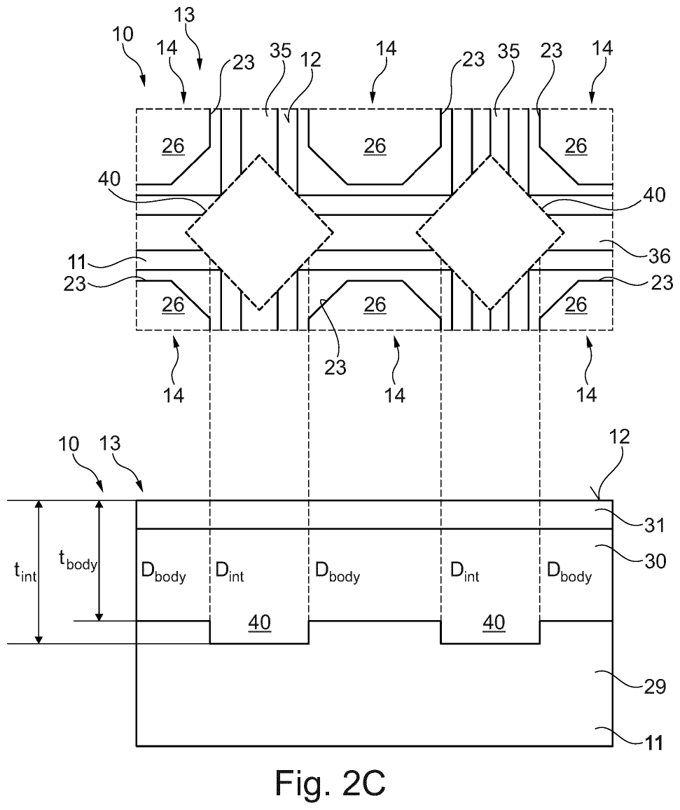

FIG. 2A illustrates a top view of a portion of a transistor device.

FIG. 2B illustrates a top view of a portion of a transistor device and the position of second body regions.

FIG. 2C illustrates a top view and a cross-sectional view of a portion of a transistor device.

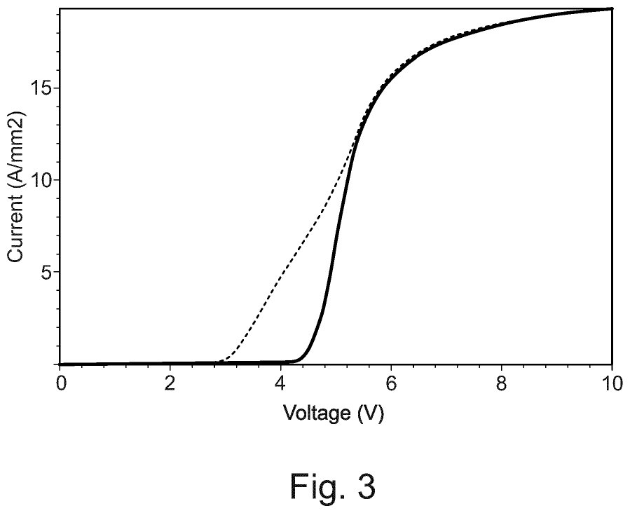

FIG. 3 illustrate a graph of current against voltage for a transistor device including a body region with locally increased doping.

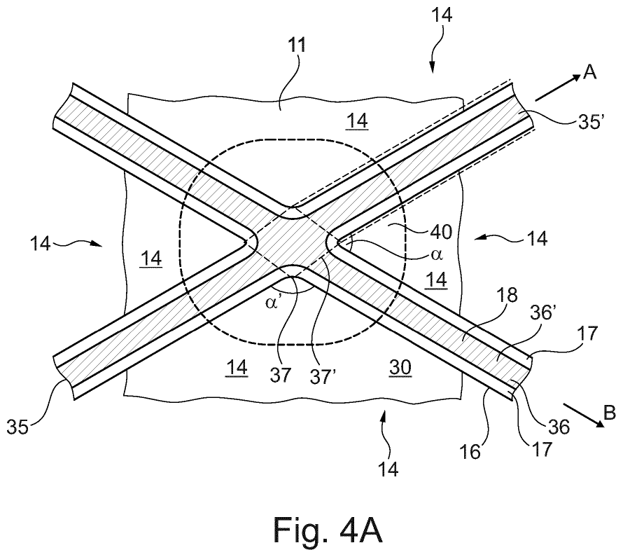

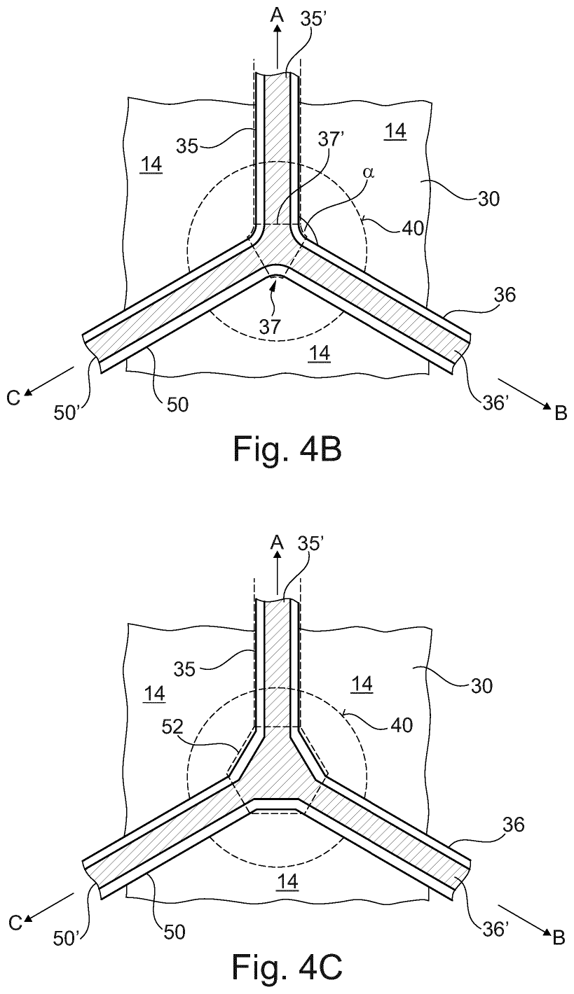

FIG. 4, which includes FIGS. 4A to 4C, illustrates portions of a gate grid structure according to various embodiments.

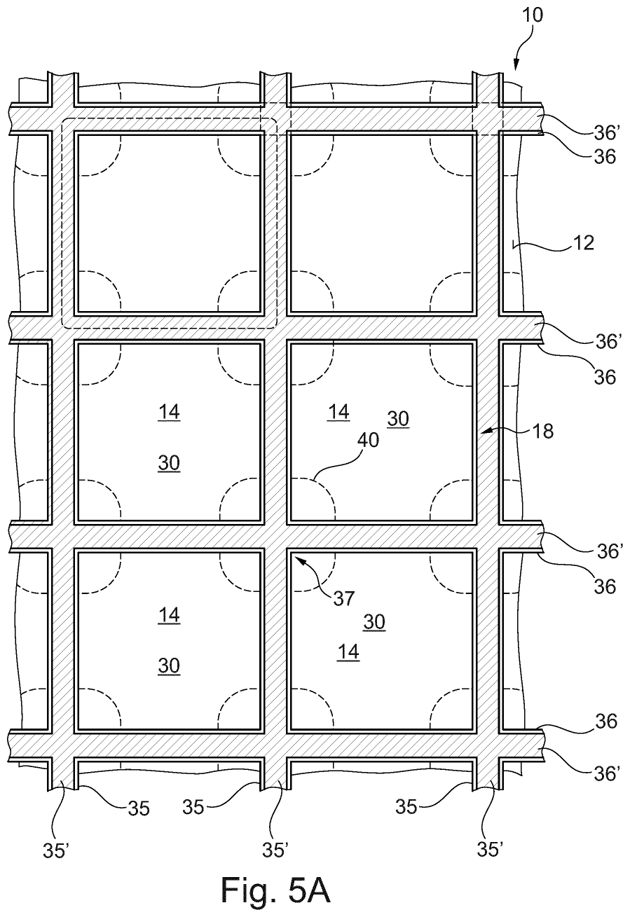

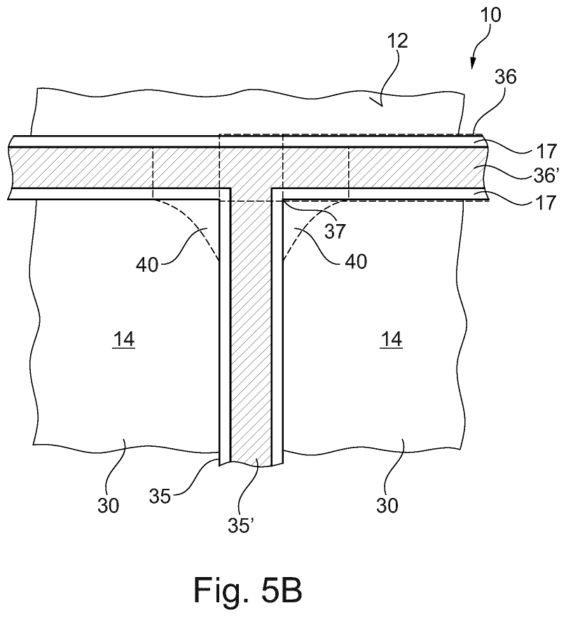

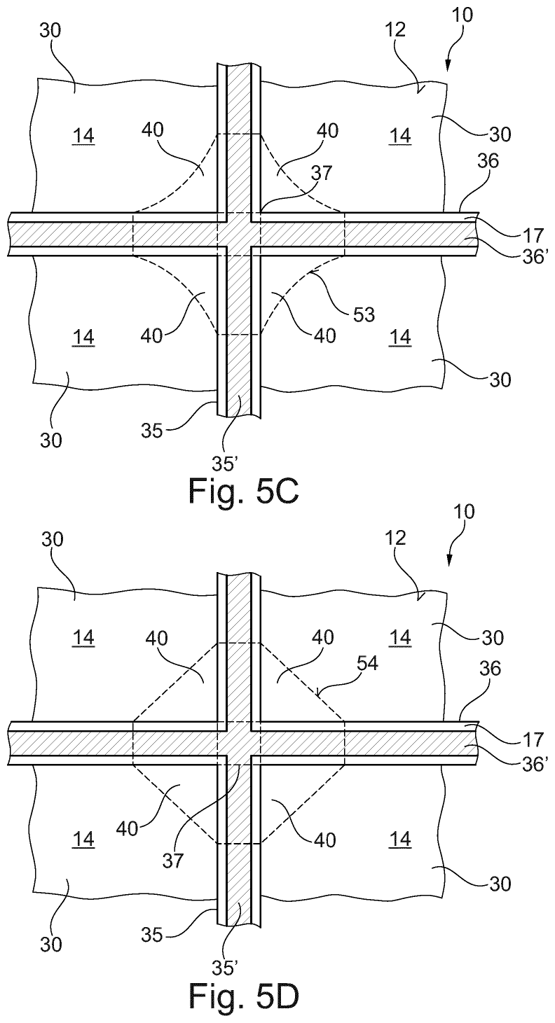

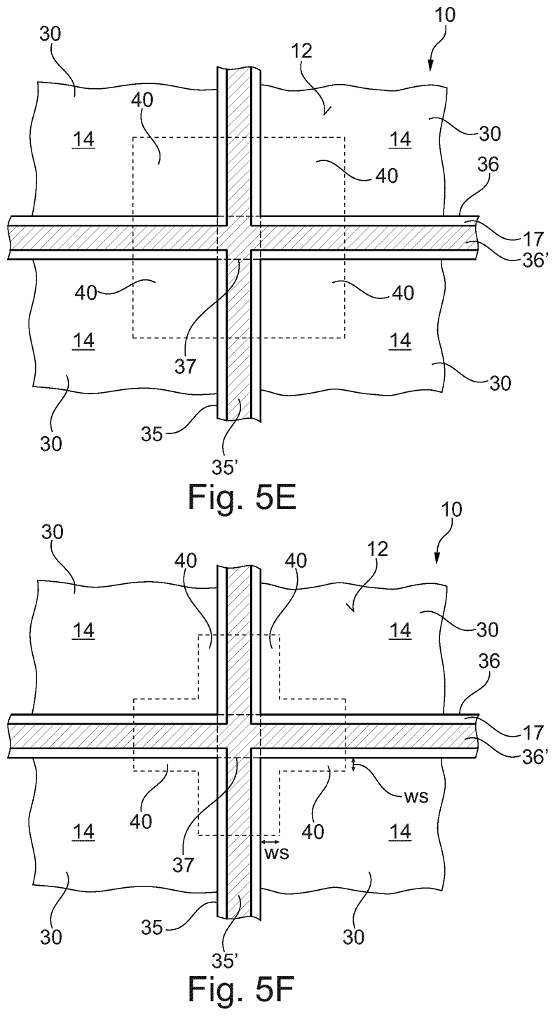

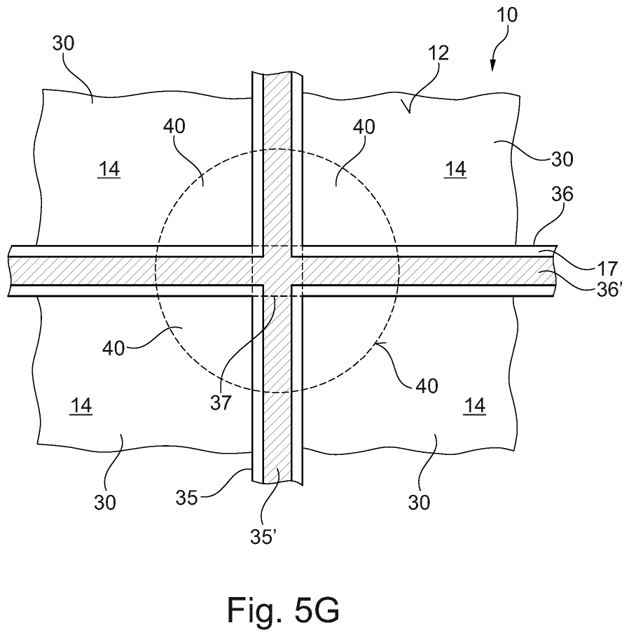

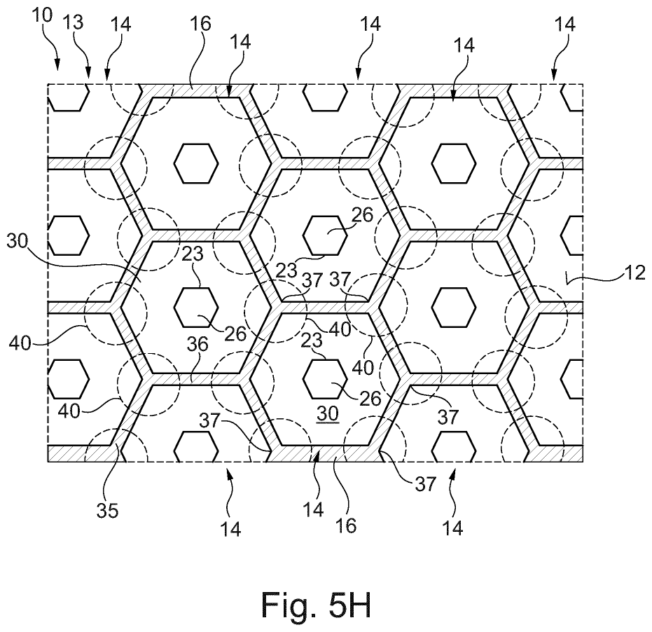

FIG. 5, which includes FIGS. 5A to 5H, illustrates portions of a gate grid structure according to various embodiments.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The FIGS. illustrate relative doping concentrations by indicating “−” or “+” next to the doping type “n” or “p”. For example, “n⁻” means a doping concentration which is lower than the doping concentration of an “n”—doping region while an “n⁺”—doping region has a higher doping concentration than an “n”—doping region. Doping regions of the same relative doping concentration do not necessarily have the same absolute doping concentration. For example, two different “n”—doping regions may have the same or different absolute doping concentrations.

MOSFET devices using needle-shaped field plates positioned in needle-shaped field plate trenches can suffer from a strong RonA(VGSTH) dependency, which can prevent the use of this design concept for low voltage technologies, where RonA below 10V is relevant. Such devices can exhibit so called “early turn on”.

It is thought that the grid-like gate design commonly used for transistor structures including an array of needle-shaped field plate trenches leads to a non-homogeneous VGSTH within the transistor cell. Without wishing to be bound by theory, the observed behavior can be described by two MOSFETs coupled in parallel that have different threshold voltages. For example, for a grid-like gate structure, each transistor cell can be considered to include a corner MOSFET arranged at the intersection between two gate trench sections extending in different lateral directions and a straight MOSFET formed with a central section of the gate trench section, i.e. a section of the gate trench section positioned between two neighbouring intersections.

In order to turn on both MOSFETs at the same time (low RonA at any VGSTH), VGSTH of both MOSGETs should match, because otherwise the MOSFET with low VGSTH will conduct first. This leads to a higher RonA in comparison to a homogeneous VGSTH within the cell. With the same body doping level, the corner MOSFET will show a lower VGSTH than the straight MOSFET due to a two directional field effect at the corner of the transistor cell formed by the intersection of the two gate sections (VGSTH measured=min(VGSTH corner, VGSTH straight)).

According to embodiments described herein, a more uniform threshold voltage (VGSTH) is achieved by locally tuning the threshold voltage within the transistor cell. This can be achieved, for example, by locally increasing the doping level of the body region at the intersections of the grid-like gate structure, so as to locally increase the VGSTH of the corner MOSFET and mitigate the effects of the two dimensional electric field at the corner of the transistor cell, i.e. at the intersection of the gate trench sections.

In some embodiments, a second body (“corner body”) is introduced into the transistor structure which is only present in the corners, i.e. at the intersections of the gate trenches. This enables the VGSTH of the corner and straight MOSFET to be tuned separately and to be set to have a more similar value that may even be substantially the same. Furthermore, the additional corner body enables the length of the accumulation region in the gate crossings to be tuned separately. Due to locally higher open area, the gate crossings may be etched deeper in comparison to the straight parts. This further enables a QGD tuning.

A second body implant in the gate crossing or intersection region is provided which enables a homogenous VGSTH in needle trench MOSFET technologies. In addition, the QGD in the gate crossing can be reduced. The additional implantation can be detected by top view images, in which the needle trench design and grid-like gate design can be seen, and transfer characterization measurements. Furthermore, the variation in the doping level of the body region can be detected with SSRM (Scanning Spreading Resistance Microscopy) or methods for the characterization of the doping profile of the MOSFET cell, such as SIMS (Secondary Ion Mass Spectroscopy).

FIG. 1 illustrates a cross-sectional view of a transistor device 10 according to an embodiment. The transistor device 10 includes a semiconductor body 11 having a main surface 12, a cell field 13 comprising a plurality of transistor cells 14 and an edge termination region 15 which laterally surrounds the cell field 13. The plurality of transistor cells 14 in the cell field 13 may all have substantially the same structure.

The cell field 13 contributes to the switching of the transistor device 10, whereas the edge termination region 15 serves to provide electrical isolation between the active device region, i.e. the cell field 13, and the edge region of the device.

Referring to the cross-sectional view of FIG. 1, the cell field 13 comprises a gate trench structure including plurality of gate trenches 16 in the main surface 12 of the semiconductor body 11, each gate trench 16 comprising a gate dielectric 17 lining the gate trench 16 and an electrically conductive gate electrode 18 arranged in the gate trench and on the gate dielectric 17. The gate trenches 16 and gate electrode 18 are elongate having a long direction that extends into the plane of the drawing. The gate electrodes 18 may comprise polysilicon or metal.

The transistor device 10 further comprises a charge compensation structure which comprises a plurality of electrically conductive field plates 26, each field plate 26 being positioned in a field plate trench 23. The field plate trenches 23 extend into the major surface 12 of the semiconductor body 11 and are defined by a base 24 and sidewalls 25 which extend substantially perpendicular to the main surface 12. The field plate 26 is electrically conductive and may be formed of polysilicon, for example. The field plate trench 23 is lined with an electrically insulating layer 39, which is commonly known as a field oxide, to electrically isolate the electrically conductive field plate 26 from the semiconductor body 11. The field oxide 39 typically has a larger thickness than the gate dielectric 17.

The semiconductor body 11 may be formed of a monocrystalline semiconductor body such as a monocrystalline silicon wafer. In some embodiments, the semiconductor body may be formed by epitaxial semiconductor layer, for example an epitaxial silicon layer.

The transistor device 10 is a vertical transistor device with a drain region 27 positioned at a second main surface 28 of the semiconductor body which opposes the main surface 12. The semiconductor body 11 may form the drift region 29 of the transistor device 10 and be lightly doped with a first conductivity type, e.g. n-type. The drain region 27 is highly doped with the first conductivity type, for example n-type. A body region 30 is positioned on the drift region 29 and the comprises dopants of a second conductivity type, e.g. p-type, which opposes first conductivity type. A source region 31 is positioned on or in the body region and comprises dopants of a first conductivity type.

A metallic layer, indicated schematically in FIG. 1 by the line 32, may be positioned on the drain region 27 to form a drain contact for the transistor device 10 on the rear surface. A conductive layer, indicated schematically in FIG. 1 by the line 33, may be positioned on the main surface 12 of the semiconductor body 11 on the cell field 13 which is electrically coupled to the source region 31 and the field plates 26 which forms a source contact for the transistor device 10. The gate electrodes 18 may be coupled to a gate contact, indicated schematically in FIG. 1 by the line 34, for the transistor device 10 which is positioned on the main surface 12 laterally adjacent source contact. The gate electrodes 18 may comprise metal or polysilicon.

FIG. 2A illustrates a top view of a portion of the transistor device 10. In the top view, it can be seen that each of the field plate trenches 23 and the field plates 26 is columnar and has a needle shape. In this embodiment, the field plate trenches 23 are shown as having an octagonal outer contour. However, the outer contour is not limited to this form shape and may have other shapes, such as circular, square, hexagonal and so on. The columnar field plate trenches 23 and consequently the field plate 26 positioned within them are arranged in a regular square grid array of rows and columns. However, the array is not limited to a square grid array and other arrays such as a hexagonal array may be used.

In the top view of FIG. 2A, it can also be seen that the gate trenches 16 and the gate electrodes 18 form part of a grid shape so that the transistor device 10 includes a gate trench structure having longitudinal sections 35 extending in the Y direction and transverse sections 36 extending in the X direction. The longitudinal sections 35 and transverse sections 36 cross or intersect one another at intersections 37. The gate electrode 18 also has a grid form including longitudinal sections 35′ extending in the Y direction and transverse sections 36′ extending in the X direction that intersect one another at intersections 37′. Each intersection 37 is positioned at the corner of four adjoining transistor cells 14.

In the embodiment illustrated in FIG. 2, the spacing between neighbouring longitudinal sections 35 and the spacing between neighbouring transverse sections 36 is substantially the same such that a square grid is formed. One columnar field plate trench 23 and its associated columnar field plate 26 is positioned in each of the square regions bounded by and spaced apart from two neighbouring longitudinal sections 35 and two neighbouring transverse sections 36 of the grid-like gate trench 16. The intersections 37 are also arranged in a regular array of rows and columns.

Also illustrated in FIG. 2A is the position of a contact 38 which is positioned on the field plate 26 and which is laterally spaced apart from the grid of the gate trench 16

As mentioned above, the intersections 37 of the gate structure can cause two dimensional electric field effects which result in a local decrease of the threshold voltage of the transistor cell 14 in the region adjacent and bounded by the perpendicular corner of the gate structure formed at the intersection 37 compared to the threshold voltage of other parts of the transistor cell 14, for example adjacent the field plate trench 23 or adjacent portion of the longitudinal section 35 or transverse section 36 positioned midway between two immediately neighbouring intersections 37. This effect can be mitigated by locally tuning the threshold voltage VGSTH within the area of the transistor cell 14, i.e. VGSTH has different values at different positions within the transistor cell 14, for example at different positions within the region enclosed by a ring of the gate trench grid.

According to some embodiments, the effect of the two-dimensional electric field at the intersection of two gate trenches can be mitigated by locally tuning at least one parameter of the body region 30, for example doping level and/or depth, within the area of the transistor cell 14. In some embodiments, the body region 30 of the transistor device 10 includes at least one parameter having a value that varies depending on the lateral position within the transistor device 10 and also on its lateral position within each transistor cell 14.

In some embodiments, the depth t of the body region 30 and/or a doping level D of the body region 30 varies as a function of its lateral position. The maximum variation in the doping level D of the body region 30 can be around 10 times. The variation may be a minimum of 1.1 times. By locally tuning the doping level D and/or depth t of the body region 30 within the cell 14, the threshold voltage can be locally tuned within the cell so that the threshold voltage is more uniform and early turn on of the transistor device 10 can be avoided.

FIG. 2B illustrates a top view of the portion of the cell field 13 of the transistor device 10 in which regions 40 of the body region 30 are schematically indicated which have a value of a parameter which differs from the value of this parameter outside of the indicated regions 40. In the embodiment illustrated in FIG. 2B, the doping level of the body region 30 within the regions 40, Dᵢₙₜ, is higher than the doping level of the body region 30 laterally outside of the regions 40, D_{body}. For example, Dᵢₙₜ>1.1D_{body} or Dᵢₙₜ>1.2D_{body}.

Each of the regions 40 is arranged at an intersection 37 between a longitudinal gate trench section 35 and a transverse gate trench section 36. Each region 40 has a lateral extent such at it extends from the inner edge of the gate trench section 35, 36 in the immediate vicinity of the intersection 37 towards the field plate trench 23 by a distance. This results in the threshold voltage being locally increased within the region 40 compared to outside of the region 40 so that the effect of the electric field extending from two perpendicular directions at the corner of the transistor cell 14 formed at the intersection 37 by the longitudinal section 35 and transverse section 36 of the gate trench 16 can be mitigated. The threshold voltage of the transistor cell 14 is more uniform or homogeneous over the area of the transistor cell and therefore over the area of the cell field 13.

In the embodiment illustrated in FIG. 2B, each of the regions 40 is depicted as a discrete region spaced apart from its neighbouring discrete regions 40 such that the discrete regions 40 are arranged in a regular array of rows and columns. However, the variation in the value of the parameter, e. g. doping level of the body region 30, in lateral directions may not be abrupt and have a more gradual change as a function of distance.

The columnar field plate trenches 23 and the columnar field plates 26 are arranged in a regular square grid array. The regions 40 are also arranged in a regular square array that has the same pitch but that that is laterally offset from the square grid array of the field plate trenches 23.

The region 40 as depicted in the drawings may correspond to the opening in a mask used for locally implanting additional dopants into the body region 30. In these embodiments, the discrete regions 40 may indicate a region in which a second body implant to implant dopants of the second conductivity type is performed so that the doping level of the body region 30 at and around the intersections 37 between the longitudinal gate trench sections 37 and transverse gate trench sections 36 is locally increased.

The doping level of the body region 30 varies as a function of the lateral position within the cell field 13 and within each transistor cell 14, for example in a lateral direction between the field plate trench 23 to the gate trench 16, in particular to the intersection 37 of the gate trench 16 of that transistor cell 14.

The regions 40 are depicted in FIG. 2 as having the form of a square with the corners of the square aligned with the centre of the longitudinal sections 35 and transverse sections. However, the region 40 is not limited to having this particular shape. Further examples are illustrated in FIGS. 4 and 5.

The doping level of the body region 30 at the intersection 37 of the gate trench structure 16 differs from the doping level of the body region 30 at the columnar field trench 23. For example, the doping level of the body region 30 may be higher at in a portion of the semiconductor body 11 positioned immediately adjacent the intersection 37 than in a portion of the semiconductor body positioned immediately adjacent the columnar field trench 23.

FIG. 2C illustrates a top view and a cross-sectional view of a portion of the semiconductor body 11 and indicates a lateral variation in the depth of the body zone 30.

In some embodiments, the depth, tᵢₙₜ, of the body region 30 from the main surface 12 of the semiconductor body 11 in the region 40 differs from the depth, t_{body}, of the body region 30 that bounds the columnar field trench 23. For example, the depth of the body region immediately adjacent the intersection 37 may be greater than the depth of the body region immediately adjacent the columnar field plate trench 23.

The depth of the body region 30 can also be defined as the position of the pn junction between the body junction 30 and the drift region 29.

In some embodiments, within each transistor cell 14, a maximum net dopant concentration of the semiconductor body 11 at a position adjacent a side wall of the intersection 37 of the gate trench 16 is at least 1.1 and at most ten times a maximum net dopant concentration of the semiconductor body 11 at a position adjacent a side wall of the columnar field plate trench 23.

In some embodiments, within each transistor cell 14, a maximum net dopant concentration of the semiconductor body 11 at a position adjacent the gate dielectric 17 positioned on the side wall of the gate trench 16 forming the side wall of the intersection 37 is at least 1.1 times or at least 1.2 times and at most ten times a maximum net dopant concentration of the semiconductor body 11 at a position adjacent the field oxide 39 positioned the side wall 25 of the columnar field plate trench 23.

In some embodiments, within each transistor cell 14 and in a plane of the semiconductor body 11, a maximum net dopant concentration of the semiconductor body 11 at a position adjacent a side wall of the intersection 37 of the gate trench 16 is at least 1.ltimes or at least 1.2 times and at most ten times a maximum net dopant concentration of the semiconductor body 11 at a position adjacent a side wall of the columnar field plate trench 23.

In some embodiments, within each transistor cell 14 and in a plane of the semiconductor body 11, a maximum net dopant concentration of the semiconductor body 11 at a position adjacent the gate dielectric 17 positioned on the side wall of the gate trench 16 forming the side wall of the intersection 37 is at least 1.1 times or at least 1.2 times and at most ten times a maximum net dopant concentration of the semiconductor body 11 at a position adjacent the field oxide 39 positioned the side wall 25 of the columnar field plate trench 23.

In some embodiments, within each transistor cell 14, in a plane of the semiconductor body 11 that is positioned between the main surface 12 of the semiconductor body 11 and the depth t_{body}, the maximum net dopant concentration of the semiconductor body 11 at a lateral position adjacent the side wall of the intersection 37 of the gate trench 16 is at least 1.ltimes or at least 1.2 times and at most ten times the maximum net dopant concentration of the semiconductor body 11 at the lateral position adjacent the side wall of the columnar field plate trench 23.

In some embodiments, within each transistor cell 14 and in a plane of the semiconductor body 11 that is positioned between the main surface 12 of the semiconductor body 11 and the depth t_{bodyr} a maximum net dopant concentration of the semiconductor body 11 at a position adjacent the gate dielectric 17 positioned on the side wall of the gate trench 16 forming the side wall of the intersection 37 is at least 1.1 times or at least 1.2 times and at most ten times a maximum net dopant concentration of the semiconductor body 11 at a position adjacent the field oxide 39 positioned the side wall 25 of the columnar field plate trench 23.

The variation in the level of the parameter of the body region 30 in one or more lateral directions and/or the vertical direction may be periodic and correspond to the periodic arrangement of the intersections 37. For example, the regions 40 may be arranged in a regular array corresponding to the regular array of intersections 40.

In some embodiments, at least one of the depth and doping level of the body region 30 varies laterally with a predetermined pattern, for example has a laterally regular variation in value, across the cell field 13 of the transistor device 10.

In some embodiments, such that that illustrated in FIG. 2, the regions 40 and intersections 37 are arranged in rows and columns to form a square grid array. In these embodiments, at least one of the depth and doping level of the body region 30 varies with a regular pitch along the rows and columns of the square grid array.

In some embodiments, the regions 40 and intersections 37 are arranged in a hexagonal array.

In order to provide increased doping levels in the body region 30 at predetermined regions of the semiconductor body 11, a two-stage process may be used in which dopants comprising the second conductivity type are implanted into the main surface 11 of the semiconductor body 11 uniformly and then a second implantation process is used to implant further dopants of the second conductivity type into predetermined regions of the main surface 12 of the semiconductor body 11. A body drive, or annealing treatment, may be carried out after the first implantation and before the second implantation or only after the second implantation.

In some embodiments, a first implant process is used to form the body region 30 over the entire area of the cell field 13 having a substantially uniform doping level. This first implant process can be carried out first followed by a local or area selective implantation using a second implant process so as to increase the doping level of the body region 30 at preselected regions 40, which are to correspond to the position of the intersections 37 of the gate trench structure 16.

FIG. 3 illustrates a graph of current as a function of voltage for a transistor device including columnar field plate trenches and a gate trench and gate having a grid structure and having either a body region having a uniform doping level (dotted line) or a body region with locally increased doping at the intersections of the gate trench grid structure (solid line). FIG. 3 illustrates that the value of the threshold voltage is increased for the transistor device having a body region with locally increased doping at the intersections of the gate trench grid structure.

The gate structure for a compensation structure including columnar field plates is not limited to a square grid. In other embodiments, the gate trench structure comprises a first section 35 extending in a first lateral direction A and a second section 36 extending in a second lateral direction B that is different from the first lateral direction A, wherein the second section 36 intersects with the first section 35 at an intersection 37. The angle between the first and second lateral directions 35, 36 may be greater or smaller than 90°, for example 0°<α<90° or 90°<α<180°. For example, the first and second sections 35, 36 may form a triangular, hexagonal or octagonal grid.

FIG. 4A illustrates an embodiment of a grid gate structure for a transistor device with a compensation structure including a plurality of columnar field plates arranged in an array. The grid gate structure includes a first gate trench section 35 extending in a lateral direction A and a second gate trench section 36 extending in the lateral direction B. The first section 35 and the second section 36 intersect at an intersection 37. The angle α between the lateral directions A and B is less than 90°.

The gate electrode 18 also includes first section 35′ arranged in the first gate trench section 35 and a second section 36′ arranged on the second gate trench section 36 which intersect at an intersection 37′. The angle α between the first and second sections 35′, 36′ of the gate electrode 18 is, therefore, also less than 90°. The intersection 37 is arranged between four transistor cells 14 having different shapes in plan view at this intersection, since the angle α between one pair of trench sections 35, 36 is less than 90° and the angle af between the adjoining pair of trench sections 35, 36 is greater than 90°.

The semiconductor body 11 includes a region 40 of the body region 30 which includes a higher doping level than in regions laterally adjacent the region 40. The region 40 extends outwardly from the sidewalls of the intersecting gate trench sections 35, 36. In this embodiment, the region 40 has a square type form with rounded corners with the rounded corners being positioned in the body region 30 of the respective four transistor cells 14.

FIG. 4B illustrates a gate structure including three gate trench sections which intersect at an intersection 37. The intersection 37 is positioned between three transistor cells 14. The first gate section 35 extends in a lateral direction A, the second gate trench section 36 extends in a second lateral direction B and the third gate trench section 50 extends in a third lateral direction C, whereby the lateral directions A, B and C are different. In this embodiment, the angle α between the lateral directions A and B, the angle a between the lateral directions B and C and the angle α between the lateral directions A and C is substantially the same and is around 120°. The semiconductor body 11 also includes a region 40 of the body region 30 which includes a higher doping level. The region 40 has a substantially circular shape and is centred on the intersection 37 such that region 40 extends outwardly from the side walls of the intersecting sections 35, 36, 50 towards the non-illustrated columnar field plate arranged in the centre of each transistor cell 14.

FIG. 4C illustrates a variation of the arrangement illustrated in FIG. 4B in which the joint between the neighbouring trench sections 35, 36, the neighbouring trench sections 36 and 50 and the neighbouring trench sections 50 and 35 has a inclined form 52. The semiconductor body 11 also includes body region 30 including a region 40 centered on the intersection 37 that has a higher doping level as in the embodiment illustrated in FIG. 4B.

FIG. 5, which includes FIGS. 5A to 5H, illustrates portions of a gate grid structure including a region 40 of the body region 30 positioned at the intersection 37, that has a different value of a parameter, for example a higher doping level, than at regions of the body region 30 positioned laterally adjacent this region according to various embodiments.

In the embodiments illustrated in FIGS. 5A to 5G, the gate grid structure includes a plurality of longitudinal sections 35 extending substantially parallel to one another and a plurality of transverse sections 36 extending substantially parallel to one another and intersecting one another at intersections 37 to form a square grid arrangement for the gate trench 16 and gate electrode 18.

In the embodiment illustrated in FIG. 5A, the semiconductor body 11 includes regions 40 of the body region 30 which have a substantially square shape with rounded corners, whereby the rounded corners are positioned in the body region 30 of the four transistor cells 14 such that the rounded corners point towards the columnar field plate trench (not seen in the view of FIG. 5A) at the centre of each of the four transistor cells 14.

FIG. 5B illustrates an embodiment of an intersection 37 of the gate grid structure which may, for example, be used at the edge of the cell field 13. In this embodiment, a first longitudinal trench section 35 extends from one sidewall of a second transverse trench section 35 so as to form a T-shape. In this embodiment a longitudinal section 35 extends from one side wall of a transverse section 36 with the opposing side wall of the transverse section 36 being straight. In this embodiment, the doped region 40 may be arranged so as to extend between the two adjoining sidewalls of the longitudinal section 35 and transverse section 36 and not on the opposing straight sidewall of transverse section 36.

FIG. 5C illustrates an embodiment in which the region 40 with a higher doping level extends symmetrically around the intersection 37 between the orthogonal longitudinal and transverse sections 35, 36 and has an outer contour such that the contour between intersecting sections 35, 36 bounding a transistor cell 14 is concave 53. This results in the lateral extent of the doped region 40 being greater in directions parallel to the longitudinal and transverse sections 35, 36 of the gate structure than in directions extending from the corner 51, that is formed between adjacent longitudinal and transverse sections 35, 36, in the direction of the columnar field plate trench at the centre of the transistor cell 14.

FIG. 5D illustrates an embodiment in which the contour of the body region 40 which extends between the intersecting sidewalls of a connected transverse trench section 36 longitudinal trench section 35 is substantially linear 54 rather than concave as illustrated in FIG. 5C.

FIG. 5E illustrates an embodiment in which the body region 40 has a substantially square form, with the corners being positioned in the body region 30 rather than being aligned with the longitudinal and transverse trench sections 35, 36 as in the embodiment illustrated in FIG. 2A.

FIG. 5F illustrates an embodiment in which the region 40 has a cross form such that it extends from the sidewalls of the intersecting longitudinal and transverse sections 35, 36 by a uniform distance WS.

FIG. 5G illustrates an embodiment in which the region 40 is substantially circular and is aligned symmetrically with the intersection 37 formed between a connected longitudinal section 35 and transverse section 36.

FIG. 5H illustrates portions of a gate grid structure including a region 40 of the body region 30 positioned at the intersection 37, that has a different value of a parameter, for example a higher doping level, than in regions of the body region 30 positioned laterally adjacent and outside this region 40.

In the embodiment illustrated in FIG. 5H, the gate grid structure is hexagonal and includes a plurality of first sections 35 and a plurality of second sections 36, whereby the first and second sections 35, 36 intersect one another at an angle α of around 120° to form the intersections 37 and form a gate trench 16 having a hexagonal form in plan view. The gate electrode 18 also has a hexagonal form in plan view.

A region 40 that has a different value of a parameter, for example a higher doping level, is arranged at each of the intersections 37 so that the regions 40 have a hexagonal arrangement in plan view. Each region 40 may be arranged substantially symmetrically about the intersection 37. In this embodiment, each region 40 has a substantially circular form in plan view. However, each region 40 may also have other forms, for example hexagonal or triangular. Each region 40 extends into three adjoining transistor cells 14, each of which can be considered to have a hexagonal shape in plan view.

Each transistor cell 14 includes a columnar field plate trench 23 and field plate 26. The columnar field plate trench 23 and columnar field plate 26 may also have a hexagonal shape in plan view. However, the field plate trench 23 and field plate may have other forms, for example be substantially circular in plan view.

The columnar field plate trenches 23 and the columnar field plates 26 are arranged in a hexagonal array. The regions 40 are also arranged in a hexagonal array that has the same pitch but that is laterally offset from the hexagonal array of the field plate trenches 23.

The transistor device 10 may be used in low-voltage drives (LV drives) applications, such as forklifts, e-bikes and low-speed vehicles, in which high current drive circuitry that is both reliable and compact, yet also cost competitive is desirable. In order to meet the required high current in the above-mentioned applications, one common practice is to couple many discrete MOSFET switches in parallel. In that case, the spread of the threshold voltage (Vth) from the paralleled MOSFETs is undesired, since the MOSFET with lowest Vth would not only turn on first, but also turn off last, therefore overheating by taking more than its share of current. This Vth spread should be kept low over the lifetime of a product. An unwanted early turn on in applications with paralleled MOSFETS can provoke a short in the circuitry, potentially destroying the MOSFETs and components located nearby if the energy is high enough. Some or all of these issues can be mitigated or even overcome by use of a transistor device according to one of the embodiments described herein.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-15. (canceled)

16. A transistor device, comprising:
a semiconductor body comprising a plurality of transistor cells comprising:
a drift region of a first conductivity type;
a body region of a second conductivity type forming a first pn junction with the drift region, the second conductivity type opposing the first conductivity type;
a source region of the first conductivity type forming a second pn junction with the body region;
a columnar field plate trench extending into a major surface of a semiconductor body and comprising a columnar field plate; and
a gate trench structure extending into the major surface of the semiconductor body and comprising a gate electrode,
wherein a depth and/or a doping level of the body region locally varies within the transistor cell to improve threshold voltage homogeneity within the transistor cell.

17. The transistor device of claim 16, wherein the gate trench structure comprises a first section extending in a first lateral direction and a second section extending in a second lateral direction that is different from the first lateral direction, wherein the second section intersects with the first section at an intersection, wherein the depth of the body region is greater at the intersection of the gate trench structure than in a region bounding the columnar field plate trench and/or the doping level of the body region is higher at the intersection of the gate trench structure than in a region bounding the columnar field plate trench.

18. The transistor device of claim 17, wherein a maximum net dopant concentration of the semiconductor body at a position adjacent a side wall of the intersection of the gate trench is at least 1.1 and at most ten times a maximum net dopant concentration of the semiconductor body at a position adjacent a side wall of the columnar field plate trench.

19. The transistor device of claim 17, wherein tᵢₙₜ>1.05tbody and/or Dint>1.1Dbody, where tint is the depth of the body region in the region of the intersection, tbody is the depth of the body region adjacent the columnar field plate trench, Dint is the doping level of the body region in the region of the intersection, and Dbody is the doping level of the body region adjacent the columnar field plate trench.

20. The transistor device of claim 17, further comprising a plurality of columnar field plate trenches arranged in a regular array, wherein the first section of the gate trench structure is arranged between adjacent ones of the columnar field plate trenches and the second section of the gate trench structure is arranged between adjacent ones of the columnar plate trenches.

21. The transistor device of claim 20, wherein the gate trench structure comprises a grid structure formed by a plurality of first sections intersecting a plurality of second sections and forming a plurality of intersections, and the gate electrode has a grid structure, and wherein a pair of first sections and a pair of second sections bound one of the plurality of columnar field plate trenches.

22. The transistor device of claim 21, wherein at least one of the depth and the doping level of the body region varies laterally between adjacent ones of the plurality of intersections and/or between the intersection and the columnar field plate trench.

23. The transistor device of claim 20, wherein the body region comprises a higher doping level in a region adjacent the intersection than in a region positioned between neighbouring two intersections, and/or the body region comprises a higher doping level in a region adjacent the intersection than in a region adjacent the columnar field plate trench, and/or the body region extends deeper into the semiconductor body at the intersection than in a region positioned between two neighbouring intersections, and/or the body region extends deeper into the semiconductor body adjacent the intersection than in a region positioned adjacent the columnar field plate trench.

24. The transistor device of claim 17, wherein the depth of the gate trench at the intersection is greater than the depth of the gate trench adjacent the intersection.

25. A method of fabricating a transistor device, the transistor device comprising a columnar field plate trench extending into a major surface of a semiconductor body comprising a first conductivity type, the columnar field trench comprising a columnar field plate, and a gate trench structure comprising an elongate gate trench having a length, the elongate gate trench extending into the major surface of the semiconductor body and comprising a gate electrode, the method comprising:
implanting dopants of a second conductivity type into the major surface of the semiconductor body to form a body region in the semiconductor body, wherein the second conductivity type opposes the first conductivity type; and
implanting dopants of the second conductivity type into predetermined regions of the main surface of the semiconductor body so that at least one of the depth and doping level of the body region varies laterally.

26. The method of claim 25, further comprising:
after implanting the dopants of the second conductivity type into the regions of the body region, annealing the semiconductor body.

27. The method of claim 25, further comprising:
forming a source region of the first conductivity type in the major surface of the semiconductor body.

28. The method of claims 25, wherein the gate trench structure comprises a first section extending in a first lateral direction and a second section extending in a second lateral direction that is different from the first lateral direction, wherein the second section intersects with the first section at an intersection and the discrete region is arranged at the intersection.

29. The method of claim 25, wherein the transistor device comprises a plurality of columnar field plate trenches in the major surface of the semiconductor body, the plurality of columnar field plate trenches being arranged in a regular array, and the gate trench structure comprises a grid structure formed by a plurality of first sections intersecting a plurality of second sections to form a plurality of intersections, wherein the gate electrode has a grid structure and a pair of first sections and a pair of second sections laterally surround the plurality of columnar field plate trenches, wherein the regions are arranged at the intersections so that at least one of the depth and doping level of the body region varies laterally between the columnar field plate trench and the intersection.

30. The method of claim 29, wherein the intersections of the gate trench structure are formed in the regions.
